(19) United States
(12) Patent Application Publication
(10) Pub. No.: US 2013/0247972 A1
(43) Pub. Date: Sep. 26, 2013

(54) PASSIVATION FILM STACK FOR SILICON-BASED SOLAR CELLS

(71) Applicant: APPLIED MATERIALS, INC., Santa Clara, CA (US)

(72) Inventors: Hemant P. MUNGEKAR, Campbell, CA (US); Lin ZHANG, San Jose, CA (US); Daniel SEVERIN, Maintal (DE)

(21) Appl. No.: 13/768,761

(22) Filed: Feb. 15, 2013

Related U.S. Application Data
(60) Provisional application No. 61/600,379, filed on Feb. 17, 2012.

(51) Int. Cl. H01L 31/18; H01L 31/0216

(52) U.S. Cl. CPC H01L 31/1868; H01L 31/02167
USPC 136/256; 438/57

(57) ABSTRACT

Methods of forming a passivation film stack on a surface of a silicon-based substrate are provided. In one embodiment, the passivation film stack includes a silicon nitride layer and an aluminum oxide layer disposed between the silicon nitride layer and the silicon-based substrate. The aluminum oxide layer is deposited such that the aluminum oxide layer has a low hydrogen (H) content less than about 17 atomic % and a mass density greater than about 2.5 g/cm³. The silicon nitride layer is deposited on the aluminum oxide layer such that the silicon nitride layer has a low hydrogen (H) content less than about 5 atomic %, and a mass density greater than about 2.7 g/cm³. Reduced amount of hydrogen content in the aluminum oxide layer and the silicon nitride layer prevents gas bubbles from forming in the layers and at the interface of the passivation film stack that cause the film stack to blister.

### CROSS-REFERENCE TO RELATED APPLICATIONS

This application claims benefit of U.S. Provisional Patent Application Ser. No. 61/600,379, filed Feb. 17, 2012, entitled “PASSIVATION FILM STACK FOR SILICON-BASED SOLAR CELLS”, which is herein incorporated by reference.

### BACKGROUND

1. Field of the Invention

Embodiments of the invention generally relate to methods for fabricating photovoltaic devices, and more particularly to methods of forming a passivation film stack on a surface of silicon-based solar cells.

2. Description of the Related Art

Photovoltaic (PV) or solar cells are devices which convert sunlight into direct current (DC) electrical power. A typical PV cell includes a p-type bulk silicon wafer, or substrate, with a thin layer of an n-type silicon material disposed on top of the p-type substrate. When exposed to sunlight (consisting of energy from photons), the p-n junction of the PV cell generates pairs of free electrons and holes. An electric field formed across a depletion region of the p-n junction separates the free electrons and holes, creating a voltage. A circuit from n-side to p-side allows the flow of electrons when the PV cell is connected to an electrical load. Electrical power is the product of the voltage times the current generated as the electrons and holes move through the external electrical load and eventually recombine. A plurality of solar cells is tiled into modules sized to deliver the desired amount of system power.

The efficiency of solar cells is directly related to the ability of a cell to collect charges generated from absorbed photons in the various layers. When electrons and holes recombine, the incident solar energy is re-emitted as heat or light, thereby lowering the conversion efficiency of the solar cells. Recombination may occur in the bulk silicon of a substrate, which is a function of the number of defects in the bulk silicon, or on the front or rear surface of a substrate, which is a function of how many dangling bonds, i.e., unterminated chemical bonds (manifesting as trap sites), are on the substrate surface. Dangling bonds are typically found on the surface of the substrate because the silicon lattice of substrate ends at the front or rear surface. These dangling bonds act as defect traps and therefore are sites for recombination of electron-hole pairs. Good surface passivation layers can help to reduce the number of recombination locations and improve open circuit voltage and photo current produced by solar cells.

In order to passivate a n-type emitter surface for a p-type base solar cell, for example, a passivation layer, such as an aluminum oxide (AlₓO_{y}) layer, is typically formed on the rear surface of the silicon substrate to reduce the number of dangling bonds present on the rear surface of the substrate. Aluminum oxide is not only effective in passivating the dangling bonds, but also has effective fixed charge to improve field effect passivation. A silicon nitride (SiₓN_{y}) layer may be further deposited on the aluminum oxide layer to prevent the aluminum oxide from reacting with metal back contact material (e.g., Al) during the subsequent high-temperature anneal process, sometimes referred to as a firing process. The firing process is typically performed to open vias or features in the passivate film stack to form electrical contact with the silicon substrate, allowing current collection and transport. Rear surface passivation using an AlₓO_{y}/SiₓN_{y} film stack is desirable because the silicon nitride layer may also serve as an anti-reflective coating (ARC) layer to reduce the fraction of incident radiation reflected off of the formed solar cell device. Therefore, the addition of the silicon nitride layer also complements the thickness of the aluminum oxide layer to improve rear reflectivity of the solar cell.

However, it has been observed that aluminum oxide and silicon nitride layers in a stack tend to blister when the film stack is subjected to a thermal treatment above 500° C., such as the subsequent firing process mentioned above. Particularly, film blistering or de-lamination takes place at the Si interface. The mechanism of blistering of AlₓO_{y}/SiₓN_{y} film stack is elucidated with an experimental study, indicating thermally activated interaction between aluminum oxide and silicon nitride as the root cause. Blistering of an aluminum oxide or silicon nitride layer from a silicon substrate is detrimental to passivation properties.

Therefore, there is a need for an improved method of forming a surface passivation film stack that has high thermal stability and desirable optical and passivating properties to minimize surface recombination of the charge carriers.

### SUMMARY OF THE INVENTION

Embodiments of the invention generally relate to methods for fabricating photovoltaic devices, and more particularly relate to methods of forming a passivation film stack on a surface (e.g., a p-type emitter surface) of a silicon-based substrate. In one embodiment, a method of forming a passivation layer on a solar cell substrate is provided. The method generally includes providing a substrate into a processing chamber, the substrate having a first surface and a second surface, and the second surface is generally parallel and opposite to the first surface, forming an oxide layer on the first surface of the substrate at a temperature of greater than about 300° C. in a high plasma density environment having an ion density that exceeds 10¹² ions/cm³, forming a nitride layer on the oxide layer at a temperature of greater than about 400° C., a chamber pressure of about 5 mTorr, and a high RF power density of about 0.02 W/cm² to about 0.5 W/cm².

In another embodiment, a method of forming a passivation film stack on a substrate in a processing chamber is provided. The method generally includes providing a substrate into the processing chamber, forming an oxide layer on a rear surface of the substrate, wherein the oxide layer is formed with a hydrogen (H) content less than about 17 atomic % and a mass density between about 2.5 g/cm³ and about 2.8 g/cm³, and forming a nitride layer on the oxide layer, wherein the nitride layer is formed with a hydrogen content (H) less than about 5 atomic % and a mass density greater than about 2.7 g/cm³.

In yet another embodiment, a solar cell device is provided. The solar cell device generally includes a silicon-containing substrate, the substrate having a first surface and a second surface, the second surface is generally parallel and opposite to the first surface, an emitter region formed on the first surface of the substrate, the emitter region having a conductivity type opposite to a conductivity type of the substrate, and a passivation film stack. The passivation film stack includes an oxide layer formed on the second surface of the substrate, wherein the oxide layer has a hydrogen (H) content less than about 17 atomic % and a mass density of between about 2.5 g/cm³ and about 2.8 g/cm³, and a nitride layer formed on the oxide layer, wherein the nitride layer has a hydrogen content (H) less about 5 atomic %, a mass density greater than about 2.7 g/cm³, and a refractive index of between about 2.0 to about 2.2.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic cross-sectional view of a solar cell substrate having a passivation film stack formed on a surface of the substrate in accordance with the present invention.

FIG. 2 is an exemplary process sequence used to form the passivation film stack on a surface of the solar cell substrate of FIG. 1.

### DETAILED DESCRIPTION

Embodiments of the invention generally relate to methods for fabricating photovoltaic devices, and more particularly relate to methods of forming a passivation film stack on a surface (e.g., a p-type emitter surface) of a silicon-based substrate. In various embodiments, the passivation film stack may include an aluminum oxide layer and a silicon nitride layer. The aluminum oxide layer may be disposed between the silicon-based substrate and the silicon nitride layer. The aluminum oxide layer may be deposited using any suitable deposition technique in a manner that the aluminum oxide layer is formed with a low hydroxyl (—OH) content corresponding to a low hydrogen (H) content less than about 17 atomic %, and a mass density greater than about 2.5 g/cm³. The silicon nitride layer may be deposited on the aluminum oxide layer using any suitable deposition technique in a manner that the silicon nitride layer is formed with a low hydrogen (H) content less than about 5 atomic %, and a mass density greater than about 2.7 g/cm³.

As will be discussed in more detail below, the inventors have determined that reduced amount of hydrogen content in the aluminum oxide layer may prevent gas bubbles from forming in the aluminum oxide layer and at the interface of the film stack that cause the film stack to blister when subjecting to the subsequent high-temperature firing process. Higher mass density of the aluminum oxide layer also prevents significant changes in the film properties (e.g., thickness and hydrogen concentration) of the aluminum oxide layer after the firing process, thereby improving the passivation effect of the film stack. Similarly, reducing the hydrogen content in the silicon nitride layer may also prevent gas bubbles from forming in the silicon nitride layer and at the interface of the film stack. Higher mass density of the silicon nitride layer also limits hydrogen mobility (e.g., hydrogen diffusion from the silicon nitride layer into the aluminum oxide layer) during the subsequent high-temperature firing process, thereby suppressing blistering of the film stack.

Passivation Layer Formation Process

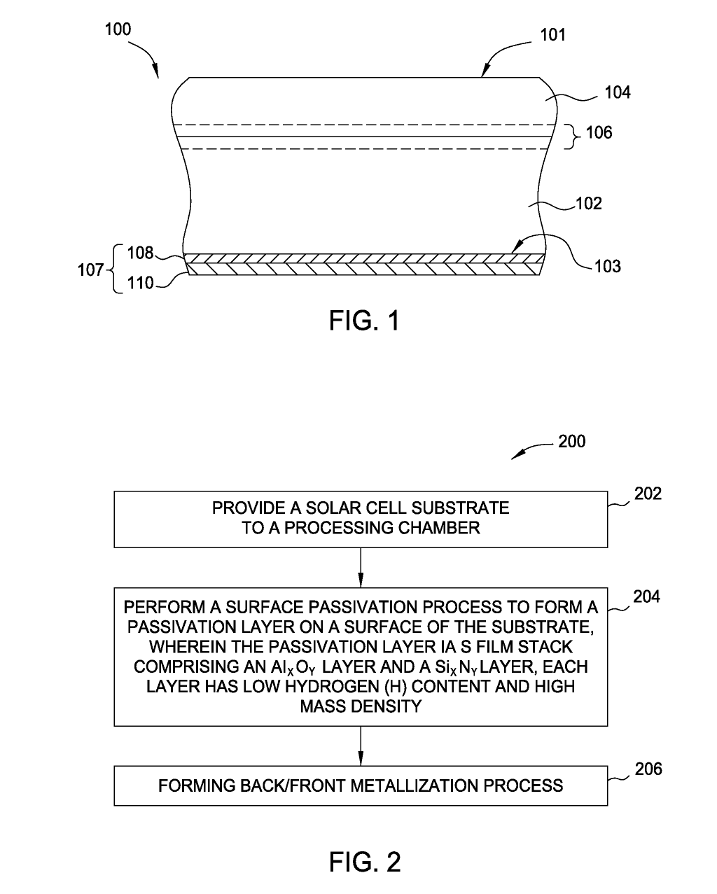

FIG. 1 illustrates a schematic cross-sectional view of a solar cell substrate 100 having a passivation film stack formed on a surface of the substrate in accordance with the present invention. FIGS. 2 illustrates an exemplary process sequence 200 used to form the passivation film stack on a surface of the solar cell substrate 100 of FIG. 1. It should be understood that while the discussion herein primarily discusses methods for processing a substrate having a n-type emitter region formed over an p-type base region, this configuration is not intended to limit the scope of the invention described herein, since the passivation layer could also be formed over a n-type base region solar cell configuration using a p-type emitter.

The process sequence 200 begins at box 202 by providing a solar cell substrate 100 into a processing chamber, such as a PECVD chamber, a CVD chamber, a PVD chamber, an ALD chamber, or any processing chamber that is suitable for surface passivation process. The substrate 100 has a front surface 101 opposite a rear surface 103. The front surface 101 is usually referred to as the light receiving surface or side of the substrate 100. The substrate 100 generally includes a base region 102, an emitter region 104, and a p-n junction region 106. The p-n junction region 106 is formed between the base region 102 and the emitter region 104 of the substrate 100, and is the region in which electron-hole pairs are generated when solar cell substrate 100 is illuminated by incident photons of light. The substrate 100 is generally a silicon substrate or at least contains silicon or a silicon-based material. In one embodiment, the substrate 100 may comprise single crystalline silicon, multi-crystalline silicon, or polycrystalline silicon, but may also be useful for substrates comprising germanium (Ge), gallium arsenide (GaAs), cadmium telluride (CdTe), cadmium sulfide (CdS), copper indium gallium selenide (CIGS), copper indium selenide (CuInSe2), gallilium indium phosphide (GaInP2), organic materials, as well as heterojunction cells, such as GaInP/GaAs/Ge or ZnSe/GaAs/Ge substrates, that are used to convert sunlight to electrical power.

In the embodiment depicted in FIG. 1, the substrate 100 is a p-type crystalline silicon (c-Si) substrate (i.e., the base region 102) having an n-type emitter region formed over the p-type c-Si substrate. The front surface 101 may be a textured surface (not shown). The n-type emitter region may be formed by doping a deposited semiconductor layer with certain types of elements (e.g., phosphorus (P), arsenic (As), or antimony (Sb)) using any suitable techniques, such as an implant process (followed by an anneal process) or a thermal diffusion process using a phosphosilicate glass (PSG), in order to increase the number of negative charge carriers, i.e., electrons.

At box 204, a surface passivation process is performed to form a passivation layer 107 on the rear surface 103 of the substrate 100. If necessary, the rear surface 103 of the substrate 100 may be exposed to a suitable pre-clean process prior to the surface passivation process for removing native oxides or contaminants thereon. The passivation layer 107 may be a single layer or a film stack that comprises a dielectric material selected from the group consisting of silicon oxide (SiₓO_{y}), silicon nitride (SiₓN_{y}), silicon oxynitride (SiON), silicon oxycarbonnitride (SiOCN), silicon oxycarbide (SiOC), titanium oxide (TiₓO_{y}), tantalum oxide (TaₓO_{y}), lanthanum oxide (LaₓO_{y}), Hafnium oxide (HfₓO_{y}), titanium nitride (TiₓN_{y}), tantalum nitride (TaₓN_{y}), hafnium nitride (HfN), hafnium oxynitride (HfON), lanthanum nitride (LaN), lanthanum oxynitride (LaON), chlorinated silicon nitride (SiₓN_{y}:Cl), chlorinated silicon oxide (SiₓO_{y}:Cl), amorphous silicon, amorphous silicon carbide, aluminum oxide (AlₓO_{y}), aluminum nitrite, or aluminum oxynitride. While not shown, it may be desirable in certain applications to passivate the front surface 101 by forming one or more layers of the dielectric material mentioned herein on the front surface 101.

In the embodiment depicted in FIG. 1, the passivation layer 107 is a film stack comprising an aluminum oxide (AlₓO_{y}) layer 108 and a silicon nitride (SiₓN_{y}) layer 110. The aluminum oxide layer 108 described herein may be stoichiometric aluminum oxide (e.g., Al₂O₃), metal-rich or oxygen-poor aluminum oxide (e.g., AlOₓ, where 0.8<x<1.5), or aluminum oxide containing one or more dopants or additional elements, such as yttrium, silicon, nitrogen, hafnium, or combinations thereof. The silicon nitride layer 110 described herein may be stoichiometric silicon nitride (e.g., Si₃N₄). The total thickness of the passivation layer 107 may be between about 2 nm and about 250 nm, in which the aluminum oxide layer 108 may be of about 1 nm to about 130 nm in thickness and the silicon nitride layer 110 may be of about 1 nm to about 120 nm in thickness. The aluminum oxide layer 108 may be formed over the rear surface 103 of the substrate 100 using any suitable deposition techniques such as such as an atomic layer deposition (ALD) process, a chemical vapor deposition (CVD) process such as a plasma enhanced chemical vapor deposition (PECVD) process or a metal organic chemical vapor deposition (MOCVD), or a physical vapor deposition (PVD) process. Thereafter, the silicon nitride layer 110 is deposited on the aluminum oxide layer 108 using any suitable deposition techniques such as a CVD process or a PVD process. Exemplary deposition approaches and process conditions are discussed in greater detail below.

The inventors have determined that the low hydroxyl (—OH) content in the aluminum oxide layer may help to reduce blistering problems. One hypothesis mechanism is that the OH bonds in the aluminum oxide layer are not thermally stable and can break when the AlₓO_{y}/SiₓN_{y} film stack is subjected to a thermal treatment at high temperature during the subsequent firing process. The breaking of OH bonds generates excessive hydrogen and oxygen atoms, which may bond with other hydrogen atoms or oxygen atoms to form hydrogen gas (H₂) or water (H₂O). These hydrogen gases or water gathering at localized sites in the aluminum oxide layer and at the interface of the resulting AlₓO_{y}/SiₓN_{y} film stack may form gaseous species, such as gas bubbles, that cause the film stack to blister when subjecting to the subsequent high-temperature firing process. While not being limited to any particular theory, the inventors believe that the reduced OH content in the aluminum oxide layer 108 can be achieved by depositing the aluminum oxide layer 108 at high plasma density and high temperature to promote bond breaking of —OH group, thereby facilitating hydrogen removal and thus film densification. A post plasma treatment or a thermal anneal process may be optionally performed to further extract OH bonds out of the aluminum oxide layer.

In one embodiment, a PECVD process is used to form the aluminum oxide layer 108 over the rear surface 103 of the substrate 100. The aluminum oxide layer 108 may be formed by flowing an aluminum-containing gas, such as trimethylaluminum (TMA), into a PECVD chamber at a flow rate of about 10 sccm to about 300 sccm per liter of chamber volume, flowing an oxygen-containing gas, such as oxygen (O₂) or nitrous oxide (N₂O), into the PECVD chamber at a flow rate of about 25 sccm to about 350 sccm per liter of chamber volume. The aluminum-containing gas and the oxygen-containing gas may be introduced into the chamber at a ratio of between about 1:1 and about 1:100. The PECVD chamber may be a parallel plate, high frequency PECVD chamber that is capable of producing high plasma density environment having an ion density that exceeds 10¹² ions/cm³. The aluminum oxide layer 108 is formed on the rear surface 103 of the substrate 100 using RF plasma source at a chamber pressure of about 5 mTorr to about 20 Torr and a frequency of 13.56 MHz, with an RF power density of about 0.002 W/cm² to about 0.5 W/cm², an electrode spacing of about 300 mils to about 650 mils, and a substrate support temperature of between about 300° C. and about 550° C. The aluminum oxide layer 108 may be deposited at a growth rate of about 50 nm/min to about 100 nm/min. The aluminum oxide layer 108 so deposited may have a thickness over 20 nm, for example over 30 nm, such as over 100 nm.

In yet an alternative embodiment, a thermal or a plasma enhanced ALD process is used to form the aluminum oxide layer 108. The ALD-deposited aluminum oxide layer is known to be able to provide a uniform thickness and the ability to adhere to the surface (e.g., the rear surface 103) very strongly by the chemical bonds. This effectively decreases the probability of the aluminum oxide layer 108 to peel off, resulting in a long lifetime and reliable rear surface passivation. During the ALD process, the rear surface 103 of the substrate 100 may be sequentially exposing to an aluminum-containing gas and an oxidizing reagent gas to form the aluminum oxide layer 108 within an ALD process chamber. The aluminum-containing gas absorbs onto the rear surface 103 of the substrate to form a monolayer of the aluminum-containing gas during a first half cycle of the ALD process. Thereafter, the oxidizing reagent gas is introduced the ALD process chamber and chemically reacted with the absorbed monolayer of the aluminum-containing gas during a second half cycle of the ALD process. The ALD process chamber may be purged between each half cycle of the ALD process, including after the first half cycle and/or the second half cycle. The ALD process chamber may be purged by flowing a purge gas or a carrier gas through the chamber and over the substrate 100. Alternatively, the ALD process may be performed by introducing the oxidizing reagent gas during the first half cycle of the ALD process and introducing the aluminum-containing gas during the second half cycle of the ALD process. The first and second half cycles and/or the purge steps are sequentially repeated until obtaining the desired thickness of the aluminum oxide layer 108.

The aluminum-containing gas may contain an alkyl aluminum compound, an alkoxy aluminum compound, an aluminum halide compound, an alkyl aluminum halide compound, an alkoxy aluminum halide compound, derivatives thereof, or combinations thereof. The oxidizing reagent gas may contain water, oxygen, nitrous oxide, ozone, hydrogen peroxide, alcohols, derivatives thereof, or combinations thereof. In one example, the aluminum-containing gas may contain an alkyl aluminum compound, such as trimethyl aluminum (TMA), and the oxidizing reagent gas may contain oxygen. During the ALD process, the substrate support is heated up to about 300° C. to about 550° C. and the chamber pressure is kept at about 5 mTorr to about 20 mTorr. The aluminum-containing gas is then introduced into the ALD process chamber at a flow rate of about 5 mg/min to about 500 mg/min. After the chamber purge, the oxidizing reagent gas is introduced into the ALD process chamber at a flow rate of about 5 sccm to about 350 sccm. In order to speed up the chemical reactions, the oxidizing reagent gas may be provided in the form of a high-energy plasma, either in-situ or remotely, at a frequency of 13.56 MHz with an RF power density of about 0.005 W/cm² to about 0.5 W/cm².

In either embodiment described above, a thermal treatment process may be optionally performed to further extract —OH bonds in the aluminum oxide layer 108 while results in densification of the aluminum oxide layer 108. The substrate 100 with the formed aluminum oxide layer may be treated with a thermal treatment, such as a plasma treatment or a thermal anneal process. The plasma treatment may be performed in a plasma treatment chamber, or in situ with the PECVD or ALD process chamber. The plasma treatment chamber and the PECVD or ALD process chamber may be disposed on the same tool and the respective processes may be performed within the same tool without breaking vacuum. The plasma treatment may be performed by supplying a plasma treatment gas to the plasma treatment chamber. The plasma treatment gas may include an oxygen-containing gas such as oxygen (O₂), nitrogen dioxide (NO₂), dinitrogen monoxide (N₂O), or other suitable gas such as noble gas which could lead to densification of the aluminum oxide layer 108.

During the plasma treatment process, the plasma treatment gas may be supplied into the plasma treatment chamber at a flow rate from about 5 sccm to about 2000 sccm. Power may then be applied to the chamber to generate a plasma. The power application and the plasma generation process may be varied by process chamber type. In one example of the plasma generating process, the plasma treatment chamber generally includes a showerhead and substrate support pedestal provide in part spaced apart electrodes. An electric field may be generated between these electrodes to ignite the plasma treatment gas introduced into chamber to provide a plasma. A pedestal is coupled to a source of radio frequency (RF) power source through a matching network, or alternatively, a RF power source may be coupled to showerhead and matching network. The RF power can be either single frequency or dual frequency ranging from about 10 KHz and about 30 MHz with an RF power density of about 0.002 W/cm² to about 0.5 W/cm² applied to the chamber to generate the plasma. The plasma may be generated from about 0.5 to about 60 seconds, such as from about 2 to about 30 seconds. While a capacitively coupled plasma source is described herein, it is contemplated that an inductively coupled plasma (ICP) source may be used. During the plasma treatment process, the substrate may be maintained at a temperature of about 300° C. to about 500° C., and the chamber pressure may be maintained from about 5 mTorr to about 20 mTorr.

The aluminum oxide layer 108 deposited by the processes described above may have a thickness over 20 nm, for example over 30 nm, such as over 100 nm, with a low hydroxyl (—OH) content corresponding to a low hydrogen (H) content less than about 17 atomic %, for example about 7 atomic %, a mass density of between about 2.5 g/cm³ and about 2.8 g/cm³, a refractive index of between about 1.62 and about 1.67, and an effective fixed charge (Qeff) of about 2×10¹² cm⁻², without blistering issues as deposited or after firing process. After the subsequent high-temperature anneal process, the hydrogen content of the aluminum oxide layer 108 can be further reduced to about 5 atomic %.

Reducing the hydrogen content in the aluminum oxide layer 108 prevents gas bubbles from forming in the aluminum oxide layer and at the interface of the film stack that blister the film stack when subjecting to the subsequent high-temperature firing process. Higher mass density of the aluminum oxide layer 108 also prevents significant changes in the film properties (e.g., thickness and hydrogen concentration) of the aluminum oxide layer 108 after the firing process, thereby improving passivation effect of the film stack.

After the aluminum oxide layer 108 has been formed on the rear surface 103 of the substrate 100, a silicon nitride layer 110 is deposited on the aluminum oxide layer 108. Particularly, the silicon nitride layer 110 is formed with a high mass density and a low hydrogen (H) content. The inventors have determined that reduced amount of hydrogen content in the silicon nitride layer is correlated with reduced blistering of the AlₓO_{y}/SiₓN_{y} film stack. As the silicon nitride layer 110 formed by a PECVD process is known to have a high hydrogen content of about 10 atom %, one hypothesis mechanism is that hydrogen gathering at localized sites in and under the silicon nitride layer (i.e., at the interface of the AlₓO_{y}/SiₓN_{y} film stack) may form gaseous species, such as gas bubbles, that cause the film stack to blister during the subsequent firing process. Also, hydrogen diffusion from the silicon nitride layer 110 into the aluminum oxide layer 108 is also assumed to cause the blistering.

Without being limited to any particularly theory, the inventors believe that reduced hydrogen (H) content in the silicon nitride layer 110 can be achieved by using: (1) high ion/neutral ratio; (2) higher fraction of radical/plasma-activated reactive species at low pressure; and (3) higher plasma sheath voltage at lower pressure during deposition of the silicon nitride layer 110. Higher plasma density at lower pressure results in stronger ion bombardment of the silicon nitride layer 110 during the deposition. The silicon nitride layer 110 as deposited has a low hydrogen (H) content, a high mass density, and a refractive index desirable for rear surface passivation of the solar cell substrate 100. Increased mass density of the silicon nitride layer 110 prevents significant changes in the properties (such as refractive index and hydrogen concentration) of the silicon nitride layer after the subsequent firing process. Increased mass density of the silicon nitride layer may also limit hydrogen mobility during the subsequent high-temperature anneal process, thereby suppressing blistering of the film stack.

In one embodiment, a PECVD process is used to form the silicon nitride layer 110. In cases where the aluminum oxide layer 108 is deposited by the PECVD process, the silicon nitride layer 110 may be deposited in-situ within the same PECVD chamber used to deposit the aluminum oxide layer 108, thereby avoiding vacuum break between the depositions. The silicon nitride layer 110 may be formed by flowing a precursor gas mixture into the PECVD chamber. The precursor gas mixture may be a combination of silane (SiH₄) and nitrogen (N₂), silane and ammonia (NH₃), or silane, ammonia, and nitrogen. In one example, the precursor gas mixture may include silane and nitrogen. Increased mass density and low hydrogen concentration of a PECVD-deposited SiN layer may be obtained by eliminating ammonia from the precursor gas mixture. If desired, a hydrogen gas may be included as a source of hydrogen. In one example, flow rates for the precursor gas mixture consisting of silane and nitrogen may be about 25 sccm to about 200 sccm and about 100 sccm to about 800 sccm, per liter of chamber volume, respectively. The PECVD chamber may be a parallel plate, high frequency PECVD chamber. In another example, flow rates for the precursor gas mixture consisting of silane, nitrogen, and ammonia may be about 25 sccm to about 200 sccm, about 100 sccm to about 650 sccm, and about 100 sccm to about 900 sccm, per liter of chamber volume, respectively. The silicon nitride layer 110 is formed on the aluminum oxide layer 108 using RF plasma source at a chamber pressure of about 5 mTorr to about 20 Torr and a frequency of 13.56 MHz, with an RF power density of about 0.002 W/cm² to about 0.5 W/cm², an electrode spacing of about 300 mils to about 650 mils, and a substrate support temperature of between about 300° C. and about 650° C. To further densify the silicon nitride layer 110, a substrate bias power may be applied to effectuate ion bombardment on the surface of the silicon nitride layer 110. The hydrogen content is believed to reduce further as a result of the film densification. In such a case, the substrate bias power may be between about 0.002 W/cm² and about 0.5 W/cm².

In an alternative embodiment, a PVD process is used to deposit the silicon nitride layer 110. The silicon nitride layer 110 may be formed by either reactive RF sputtering using a silicon-containing target in a nitrogen-containing atmosphere, or direct RF sputtering using a silicon nitride target. The PVD chamber used to deposit the silicon nitride layer 110 can be in vacuum-sealed communication with respect to the chamber for deposition of the aluminum oxide layer 108. In one example, the silicon nitride layer 110 is deposited on the aluminum oxide layer 108 within a PVD chamber by sputtering a silicon-containing target, such as silicon, using inert gas ions generated by plasma discharge of an inert gas, such as argon (Ar), helium (He), or the like. The inert gas ions are accelerated by an electric field toward the silicon target, resulting in the rejection of silicon atoms 108 and the deposition at the surface of the aluminum oxide layer while reacting with a reactive gas that is being introduced into the PVD chamber, thereby forming the silicon nitride layer 110. The reactive gas may include nitrogen, ammonia, a gas mixture of nitrogen and hydrogen, or a gas mixture of nitrogen and ammonia. The reactive sputtering process may be formed by pumping the PVD chamber down to a low pressure of about 5 mTorr to about 25 mTorr, introducing the inert gas at a flow rate of about 50 sccm to about 5000 sccm, introducing the reactive gas at a flow rate of about 50 sccm to about 2000 sccm, starting the plasma with an RF power density of about 0.002 W/cm² to about 0.5 W/cm² for about 20 seconds to about 2 minutes to sputter the silicon-containing target.

The silicon nitride layer 110 deposited by the processes described above may have a thickness over 60 nm, for example over 80 nm, with a mass density of greater than 2.7 g/cm³, a hydrogen content (H) of less than about 5 atomic %, and a refractive index of between about 2.0 and about 2.2. Reducing the hydrogen content in the silicon nitride layer 110 improves the passivation effect of the silicon nitride layer 110 while prevents gas bubbles from forming in the silicon nitride layer 110 and at the interface of the film stack that blister the film stack. Higher mass density of the silicon nitride layer 110 also prevents significant changes in the film properties of the silicon nitride layer 110 after the firing process, such as thickness, refractive index, and hydrogen concentration, thereby improving passivation effect of the film stack.

At box 206, after the silicon nitride layer 110 has been formed on the aluminum oxide layer 108, further deposition steps or processing steps, such as back/front metallization process, that may be required to manufacture the layer stack for solar cell or solar cell module can be conducted before the substrate 100 is moved out of the processing system.

It should be understood that various processes and conditions discussed above for deposition of the aluminum oxide layer 108 and the silicon nitride layer 110 are for illustrative purposes only and are not intended to limit the present invention. The film properties of the passivation film stack can be varied by adjusting the processing temperature, pressure, power density, or composition of the reactive gas mixture, etc., depending upon the application. Any suitable deposition technique is contemplated as long as the resulting AlₓO_{y}/SiₓN_{y} passivation film stack is formed with the film characteristics as described above. In addition, while the passivation film stack is illustrated to be formed on the rear surface of the substrate, it is contemplated that the aluminum oxide layer, the silicon nitride layer, or a passivation film stack having two or more layers of aluminum oxide and silicon nitride layer may be formed on the front surface of the substrate in a similar way as discussed above for the purpose of passivation.

While the foregoing is directed to embodiments of the present invention, other and further embodiments of the invention may be devised without departing from the basic scope thereof, and the scope thereof is determined by the claims that follow.

What is claimed is:

1. A method of forming a passivation layer on a solar cell substrate, comprising:
providing a substrate into a processing chamber, the substrate having a first surface and a second surface, and the second surface is generally parallel and opposite to the first surface;
forming an oxide layer on the first surface of the substrate in a high plasma density environment having an ion density that exceeds 10¹² ions/cm³; and
forming a nitride layer on the oxide layer at a chamber pressure of about 5 mTorr and a high RF power density of about 0.02 W/cm² to about 0.5 W/cm².

2. The method of claim 1, wherein the oxide layer is formed with a hydrogen (H) content less than about 17 atomic %.

3. The method of claim 1, wherein the oxide layer is formed with a mass density of between about 2.5 g/cm³ and about 2.8 g/cm³ and a refractive index of between about 1.62 to about 1.67.

4. The method of claim 1, wherein the nitride layer is formed with a hydrogen content (H) less than about 5 atomic %.

5. The method of claim 1, wherein the nitride layer is formed with a mass density greater than about 2.7 g/cm³ and a refractive index of between about 2.0 to about 2.2.

6. The method of claim 1, wherein the oxide layer comprises silicon oxide or aluminum oxide.

7. The method of claim 1, wherein the nitride layer comprises silicon nitride or aluminum nitrite.

8. The method of claim 1, wherein the substrate comprise single crystalline silicon, multi-crystalline silicon, or polycrystalline silicon.

9. The method of claim 1, wherein the substrate has an emitter region formed on the second surface of the substrate, and the emitter region has a conductivity type opposite to a conductivity type of the substrate.

10. The method of claim 1, wherein the oxide layer is formed with an effective fixed charge (Qeff) of about 2×10¹² cm⁻².

11. The method of claim 1, wherein the oxide layer is formed by a plasma enhanced chemical vapor deposition (PECVD) process or an atomic layer deposition (ALD) process

12. The method of claim 1, further comprising:
densifying the oxide layer by subjecting the oxide layer to a plasma treatment using an oxygen-containing gas.

13. The method of claim 1, wherein the nitride layer is formed by a reactive sputtering process using a silicon-containing target in a nitrogen-containing atmosphere.

14. A method of forming a passivation film stack on a substrate in a processing chamber, comprising:
providing a substrate into the processing chamber;
forming an oxide layer on a rear surface of the substrate, wherein the oxide layer is formed with a hydrogen (H) content less than about 17 atomic % and a mass density between about 2.5 g/cm³ and about 2.8 g/cm³; and
forming a nitride layer on the oxide layer, wherein the nitride layer is formed with a hydrogen content (H) less than about 5 atomic % and a mass density greater than about 2.7 g/cm³.

15. The method of claim 14, wherein the oxide layer comprises silicon oxide or aluminum oxide.

16. The method of claim 14, wherein the nitride layer comprises silicon nitride or aluminum nitrite.

17. The method of claim 14, further comprising:
forming an emitter region on a front surface of the substrate, the emitter region having a conductivity type opposite to a conductivity type of the substrate

18. The method of claim 14, wherein the oxide layer is formed by a plasma enhanced chemical vapor deposition (PECVD) process or an atomic layer deposition (ALD) process.

19. The method of claim 14, further comprising:
densifying the oxide layer by subjecting the oxide layer to a plasma treatment using an oxygen-containing gas.

20. A solar cell device, comprising:
a silicon-containing substrate, the substrate having a first surface and a second surface, the second surface is generally parallel and opposite to the first surface;
an emitter region formed on the first surface of the substrate, the emitter region having a conductivity type opposite to a conductivity type of the substrate; and
a passivation film stack, comprising:
an oxide layer formed on the second surface of the substrate, wherein the oxide layer has a hydrogen (H) content less than about 17 atomic % and a mass density of between about 2.5 g/cm³ and about 2.8 g/cm³; and
a nitride layer formed on the oxide layer, wherein the nitride layer has a hydrogen content (H) less about 5 atomic %, a mass density greater than about 2.7 g/cm³, and a refractive index of between about 2.0 to about 2.2.
